(19) United States
(12) Patent Application Publication
(10) Pub. No.: US 2008/0291952 A1
(43) Pub. Date: Nov. 27, 2008

(54) OPTICAL SEMICONDUCTOR DEVICE

(75) Inventors: Tsuyoshi Yamamoto, Kawasaki (JP); Manabu Matsuda, Kawasaki (JP); Kan Takada, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/125,220

(22) Filed: May 22, 2008

(30) Foreign Application Priority Data
May 23, 2007 (JP) 2007-136491

(51) Int. Cl. H01S 5/00

(52) U.S. Cl. 372/26; 372/50.1

(57) ABSTRACT

An optical semiconductor device with a semiconductor laser formed over a semiconductor substrate, and a modulator formed over the semiconductor substrate and continuously arranged with the semiconductor laser, wherein the semiconductor laser includes a first region having a diffraction grating with a phase shift, a second region arranged between the first region and the modulator, and in which the diffraction grating is not formed, and a common active layer formed over the first region and the second region, a first electrode injecting a current into the common active layer.

### TECHNICAL FIELD

The present invention relates to an optical semiconductor device used in optical fiber communication for example.

### BACKGROUND

Optical semiconductor devices in which a semiconductor laser and an external modulator are monolithically integrated with each other are being used as medium to long-distance light sources in optical communication systems.

Optical semiconductor devices of this kind in which a semiconductor laser and a modulator are integrated with each other have a small size of 1 mm or less. Optical semiconductor devices of this kind can therefore be mounted in small modules called “transmitter optical sub-assembly (TOSA)”. Optical semiconductor devices of this kind greatly contribute to reduction in size of optical transmitters.

Optical semiconductor devices of this kind are presently being used for transmission over a distance not exceeding 100 km in optical communication systems which are becoming mainstream a transmission rate of 10 Gb/s.

FIG. 1 is a schematic sectional view of the structure of a conventional modulator integrated laser in which a semiconductor laser 100 and a modulator 101 are integrated, showing the structure in section in a direction along a waveguide (see, for example, Japanese Laid-Open Patent Publication No. HEI9-312437).

The semiconductor laser for a laser 100 shown in FIG. 1 is a distributed feedback (DFB) laser provided with a diffraction grating 103 for causing single-mode oscillation in a multiple quantum well active layer 102.

The semiconductor laser 100 shown in FIG. 1 has the diffraction grating 103 having a λ/4 phase shift 104 with a good yield with respect to characteristics including wavelength controllability for adaptation to wavelength-division-multiplexing communication.

As shown in FIG. 1, the DFB laser 100 thus having the λ/4 shift 104 also has an antireflection (AR) coating 105 provided on an exit end surface (an end surface on the modulator side, a front side surface) of the device. The DFB laser 100 also has an antireflection (AR) coating 106 provided on a rear end surface (an end surface on the semiconductor laser side) to limit the influence of the end surface phase of the diffraction grating 103.

The active layer of the modulator 101 is a multiple quantum well active layer 110 for a modulator having a layer structure different from that of the active layer 102 of the semiconductor laser 100. The multiple quantum well active layer 110 changes the absorption therein when a voltage is applied thereto. The multiple quantum well active layer 110 produces an optical signal modulated according to the applied voltage.

In FIG. 1, reference numeral 107 denotes a laser electrode; reference numeral 108 denotes a modulator electrode; and reference numeral 109 denotes a substrate-side electrode.

Further, a region where no electrode is formed (waveguide region 111) is provided as a separation region for electrical separation between the semiconductor laser 100 and the modulator 101. This waveguide region 111 may have a layer structure different from that of the active layer of the modulator 101 (see, for example, Japanese Laid-Open Patent Publication No. 2002-324936). However, the waveguide region 111 is ordinarily provided in the same layer structure as the multiple quantum well active layer 110 for use in the modulator 101, as shown in FIG. 1.

In the above-described modulator integrated laser, the active layer of the semiconductor laser and the active layer of the modulator are made different in structure by performing regrowth. A modulator integrated laser has also been proposed in which, as shown in FIG. 2, an active layer (multiple quantum well active layer) 122 simultaneously formed by using selective area growth and having different thicknesses is used as an active layer of a semiconductor laser 120 and a modulator 121 (see, for example, Japanese Laid-Open Patent Publication Nos. HEI 9-92921 and 2000-101187). In such a modulator integrated laser, as shown in FIG. 2, the thickness of the active layer of the semiconductor laser 120 is thicker; the thickness of the active layer of the modulator 121 is thinner; and the thickness of a transition region 130 between the semiconductor laser 120 and the modulator 121, changes. In FIG. 2, reference numeral 123 denotes a diffraction grating; reference numeral 124 denotes a phase shift; reference numeral 125 denotes an antireflection coating; reference numeral 126 denotes an antireflection coating; reference numeral 127 denotes a laser electrode; reference numeral 128 denotes a modulator electrode; reference numeral 129 denotes a substrate-side electrode; and reference numeral 130 denotes a transition region.

For example, the diffraction grating 123 of the modulated integrated lasers described in Japanese Laid-Open Patent Publication Nos. 9-92921 and 2000-101187 is formed to a position in the transition region 130 formed between the semiconductor laser 120 and the modulator 121 and changing in thickness, as shown in FIG. 2. Also, the laser electrode (upper electrode) 127 is formed to a position corresponding to an intermediate portion of the transition region 130. That is, in the modulator integrated laser shown in FIG. 2, the diffraction grating 123 has its portion provided only in a region having a small change in thickness in the transition region 130 such that the effective period of the diffraction grating 123 is not substantially changed, thus enabling single-mode oscillation with stability.

In the modulator integrated laser shown in FIG. 2, the amount of absorption in the active layer 122 is large for use as a waveguide before a certain change in thickness of the transition region 130 is reached. Therefore, current injection is performed through the laser electrode 127 formed to a position corresponding to an intermediate portion of the transition region 130 where the diffraction grating 123 is not formed, thereby limiting the amount of absorption. In the transition region 130, the bandgap of the quantum well layer is increased relative to that in the semiconductor laser 120 with the change in thickness and, therefore, substantially no gain is obtained and substantially no optical output increasing effect is obtained.

In a modulator integrated laser shown in FIG. 3, a semiconductor laser 140, a modulator 141 and a semiconductor optical amplifier (SOA) 142 are integrated with each other to increase the output (see, for example, B. Kang et al., “10 Gb/s High Power Electro-Absorption Modulated Laser Monolithically Integrated with a Semiconductor Optical Amplifier for Transmission over 80 km”, Tech., Dig. OFC2003, vol. 2, pp. 751-753).

In FIG. 3, reference numeral 143 denotes a multiple quantum well active layer for the laser; reference numeral 144 denotes a diffraction grating; reference numeral 145 denotes a multiple quantum well active layer for the modulator; reference numeral 146 denotes a multiple quantum well active layer for the semiconductor optical amplifier; reference numeral 147 denotes a laser electrode; reference numeral 148 denotes a modulator electrode; reference numeral 149 denotes an amplifier electrode; reference numeral 150 denotes a high-reflection coating; reference numeral 151 denotes antireflection coating; and reference numeral 152 denotes a substrate electrode.

The modulator integrated laser described by B. Kang et al. is provided with no phase shift, as shown in FIG. 3, while the high-reflection coating (HR coating) 150 is formed on a device end surface on the semiconductor laser side.

Modulator integrated lasers such as those described above are very small-sized light sources but are incapable of obtaining a high optical output in a case where a phase shift is provided in the diffraction grating and where AR coatings are formed on opposite end surfaces of the device.

A high output is primarily in demand, for example, in use for transmission over 80 km at 10 Gb/s in particular. In a modulator under conditions for obtaining wavelength chirp enabling transmission over 80 km, however, the loss is so high that the desired high output cannot be obtained.

Devices presently put to commercial uses have an average optical output of about +2 dBm at the time of modulation, smaller by several decibels than that of modulators using LiNbO₃ as a ferroelectric, and there is a demand for increasing the output.

On the other hand, in a case where a semiconductor optical amplifier is further integrated to increase the output (see FIG. 3), the chip size, the number of electrodes and the power consumption are increased and a need arises for separately controlling the semiconductor optical amplifier.

That is, the semiconductor optical amplifier is connected to the conventional modulator integrated laser through the waveguide region, and the chip size is correspondingly increased.

Also, another electrode for injecting a current into the semiconductor optical amplifier is added and the number of electrodes is increased thereby. There is also a need to separately control the semiconductor optical amplifier.

Further, due to a need for current injection into the semiconductor optical amplifier, the power consumption is increased. In particular, with the semiconductor optical amplifier connected to the modulator constituting the modulator integrated laser through the waveguide region to amplify light modulated with the modulator, it is necessary to amplify the modulated light without causing any distortion in the modulated light. In this case, there is a need to increase the level of the injected current according to the input level of the modulated light, so that the power consumption is increased and complicated control is required.

Also, setting the optical gain of the semiconductor amplifier to a high value increases the quantity of light returned to the semiconductor laser by residual reflection on the device end surfaces with AR coating. This returned light may badly influence the characteristics of the semiconductor laser including wavelength variation.

### SUMMARY

An optical semiconductor device according to an aspect of the present invention a semiconductor laser formed over a semiconductor substrate, and a modulator formed over the semiconductor substrate and continuously arranged with the semiconductor laser, wherein the semiconductor laser includes a first region having a diffraction grating with a phase shift, a second region arranged between the first region and the modulator, and in which the diffraction grating is not formed, and a common active layer formed over the first region and the second region, a first electrode injecting a current into the common active layer.

### BRIEF DESCRIPTION OF THE DRAWINGS

FIG. 1 is a schematic sectional view of the construction of a conventional modulator integrated laser;

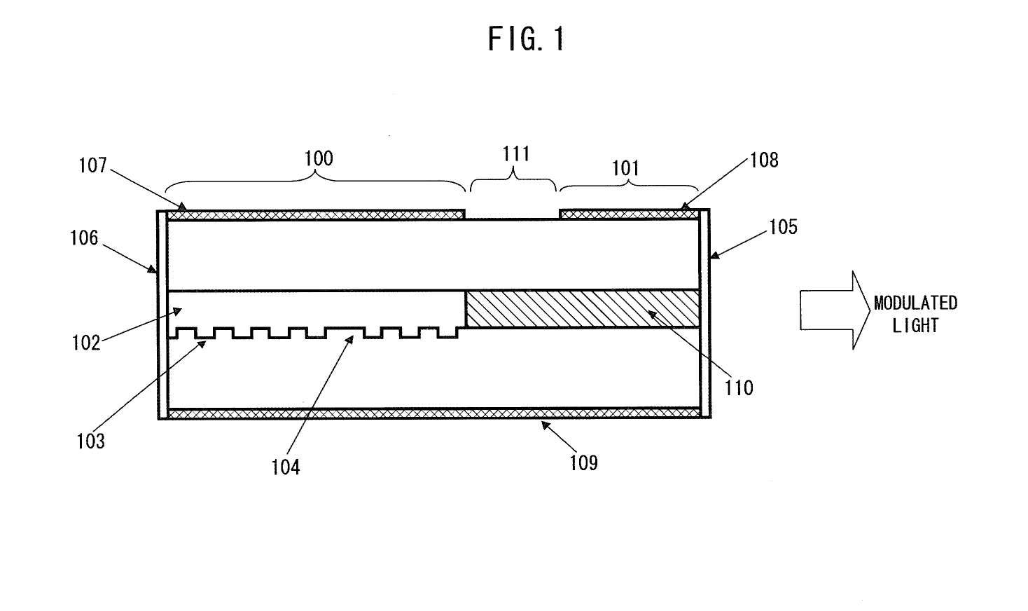

FIG. 2 is a schematic sectional view of the construction of another conventional modulator integrated laser;

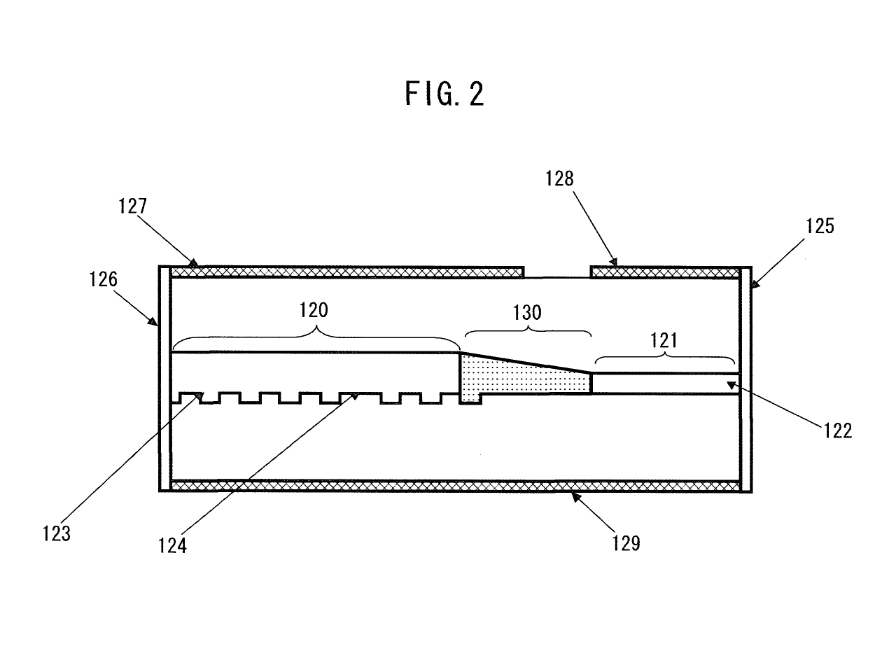

FIG. 3 is a schematic sectional view of the construction of a device having a semiconductor optical amplifier further integrated with the conventional modulator integrated laser;

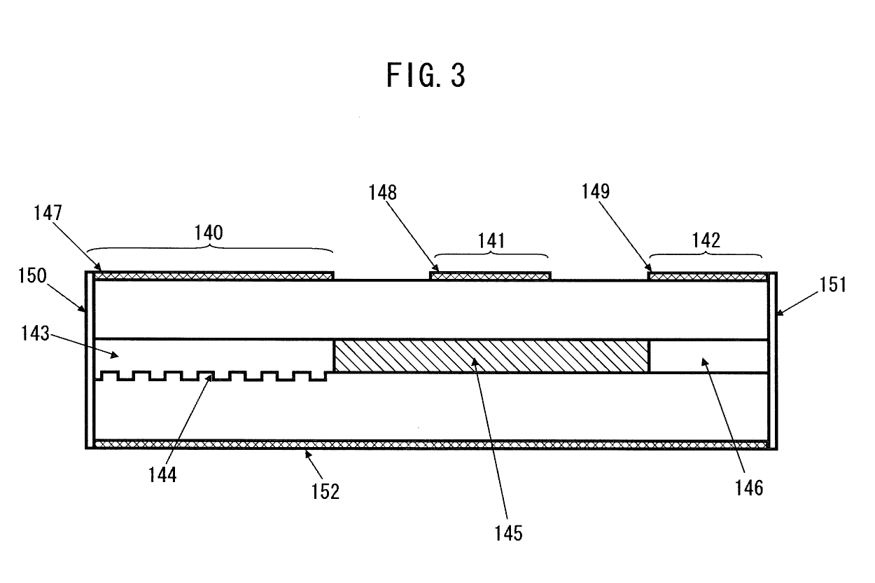

FIG. 4 is a schematic sectional view showing the construction of an optical semiconductor device according to an embodiment of the present invention;

FIG. 5 is a diagram showing the relationship between the length of a diffraction grating non-formation region and the optical output in the optical semiconductor device according to the embodiment of the present invention; and

FIG. 6 is a schematic sectional view of the construction of an optical semiconductor device according to a modification of the embodiment of the present invention.

### DETAILED DESCRIPTION OF THE EMBODIMENTS

An optical semiconductor device according to an embodiment of the present invention is a modulator integrated laser 4 in which a semiconductor laser (distributed feedback (DFB) laser provided with an internal diffraction grating having a λ/4 phase shift in this embodiment) 2 and a modulator (an electric-field absorption type of modulator in this embodiment) 3 are monolithically integrated with each other on a semiconductor substrate (an n-type InP substrate in this embodiment) 1. Antireflection coatings 5 and 6 are formed on opposite end surfaces of the modulator integrated laser 4.

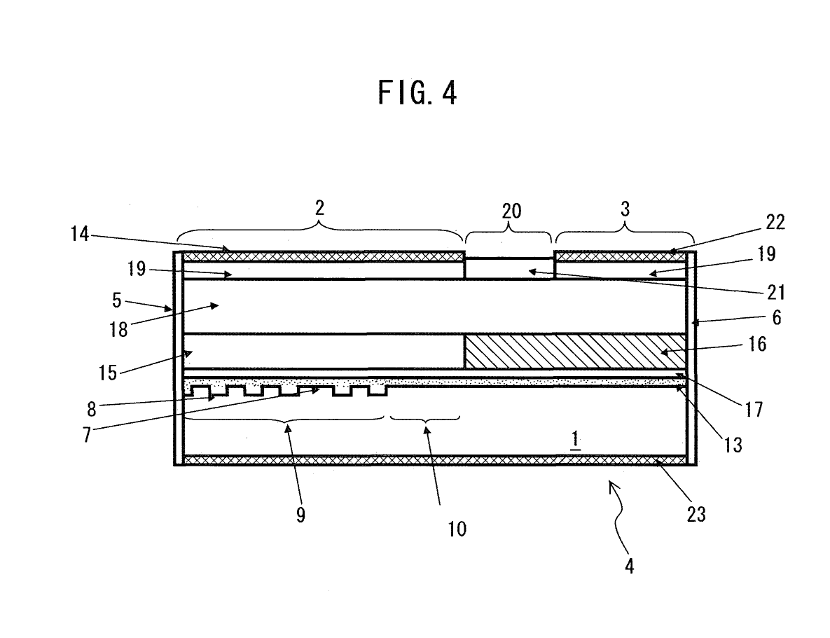

In particular, the semiconductor laser 2 has, as shown in FIG. 4, a diffraction grating formation region (resonator region) 9 where a diffraction grating 8 having a λ/4 phase shift 7, and a diffraction grating non-formation region (amplification region) 10 where the diffraction grating 8 is not formed.

The period of the diffraction grating 8 is set so that the oscillation wavelength is 1.55 μm. Also, the depth of the diffraction grating 8 is set so that, for example, the coupling coefficient k is about 45 to 55 cm⁻¹. However, the present invention is not limited to these settings.

The λ/4 phase shift 7 is formed on the modulator 3 side of a center of the diffraction grating formation region (resonator region) 9 (on the diffraction grating non-formation region 10 side, the output end surface side, the front end surface side). In this way, the optical output of modulated light (laser light) emitted from the exit end surface can be increased.

In the present embodiment, as shown in FIG. 4, the resonator region 9 is provided on the one device end surface side (the rear end surface side, the left-hand side as viewed in FIG. 4), while the amplification region 10 is provided outside the resonator region, i.e., on the modulator 3 side of the resonator region 9. That is, the diffraction grating formation region 9 where the diffraction grating 8 is formed and the diffraction grating non-formation region 10 where the diffraction grating 8 is not formed are provided in series along the optical waveguide direction (i.e., along the active layer) on the surface of the n-type InP substrate 1 (i.e., on the interface between the n-type InP substrate 1 and a waveguide layer 13 formed of n-type InGaAsP), the diffraction grating formation region 9 being provided on the device end surface side, the diffraction grating non-formation region 10 being formed on the modulator 3 side.

To operate the semiconductor laser 2, current injection into an active layer (an AlGaInAs strained-layer multiple quantum well active layer for the laser in this embodiment) 15 in the resonator region 9 and the amplification region 10 is performed by means of one p-side electrode 14 for the laser. Therefore the resonator region 9 and the amplification region 10 are in such a state that currents are injected into these regions at substantially the same current densities. Also, as mentioned above, the amplification region 10 is provided on the modulator 3 side of the resonator region 9 continuously with the resonator region 9 (that is, the semiconductor laser 2 has, on the modulator 3 side of the resonator region 9 where the diffraction grating 8 is provided, the amplification region 10 where the diffraction grating 8 is not provided). Consequently, single-mode continuously oscillated light of a relatively high light power (CW light) from the resonator region (diffraction grating formation region) 9 enters the amplification region (diffraction grating non-formation region) 10 in one direction. In the amplification region 10, a gain-saturated low-amplification condition is automatically obtained and amplification using gain saturation is performed.

Because amplification using gain saturation is performed in the amplification region 10 as described above, increasing the optical gain above a certain high value can be avoided. In this way, characteristics of the semiconductor laser 2 can be prevented from being influenced by return light due to residual reflection on the device end surface (the end surface on the right-hand side as viewed in FIG. 4). That is, in the modulator integrated laser 4, if light returned to the semiconductor laser 2 is increased by residual reflection, it badly influences the characteristics of the semiconductor laser 2 including wavelength variation, even in the case where the antireflection coating 6 is formed on the device end surface on the exit side (the front side; the right hand side as viewed in FIG. 4). In the case where the amplification region (diffraction grating non-formation region) 10 is provided on the modulator 3 side of the resonator region (diffraction grating formation region) 9 as described above, return light is also amplified in the amplification region 10. Therefore, an influence on the characteristics of the semiconductor laser 2 of return light due to residual reflection on the device end surface can be prevented by avoiding increasing the optical gain in the amplification region 10 above a certain high value.

Also, the above-described arrangement makes it possible to increase the optical output of modulated light output from the device end surface through the modulator with the respect to the same injection current as that in the conventional modulator integrated laser in which a diffraction grating is formed through the entire length of the semiconductor laser.

The resonator region 9 and the amplification region 10 differ from each other in that, as shown in FIG. 4, the diffraction grating 8 is provided on the surface of the n-type InP substrate 1 (i.e., on the interface between the n-type InP substrate 1 and the n-type InGaAsP waveguide layer 13) in the resonator region (diffraction grating formation region) 9, while the diffraction grating 8 is not provided on the surface of the n-type InP substrate 1 in the amplification region (diffraction grating non-formation region) 10. In other respects, the layer structures of the resonator region 9 and the amplification region 10 are identical to each other.

More specifically, as shown in FIG. 4, each of the resonator region 9 and the amplification region 10 has a layer structure in which the n-type InGaAsP waveguide layer 13 (thickness: 0.1 μm), an n-type InP layer 17 (thickness: 0.05 μm, etching stop layer), the AlGaInAs-based strained-layer multiple quantum well active layer 15 for the laser, a p-type InP cladding layer 18 (thickness: 1.65 μm) and a p-type InGaAs contact layer 19 (thickness: 0.3 μm) are successively stacked on the n-type InP substrate 1. That is, the resonator region 9 and the amplification region 10 have the same active layer 15.

The AlGaInAs-based strained-layer multiple quantum well active layer 15 for the laser has, for example, as a multiple quantum well structure, a seven-layer structure formed of an AlGaInAs well layer having a compressive strain of 1.2% and a thickness of 5.1 nm and an AlGaInAs barrier layer having no strain, a thickness of 10 nm and a bandgap wavelength of 1.2 μm, and is formed as an AlGaInAs/AlGaInAs compressively-strained multiple quantum well active layer having a photoluminescence wavelength of 1.55 μm. However, the present invention is not limited to this.

Also, the p-side electrode (upper electrode) 14 for the laser formed of Ti/Pt/Au for example is provided on the p-type InGaAs contact layer 19, as shown in FIG. 4. That is, one (single) upper electrode 14 is formed above the resonator region 9 and the amplification region 10 to perform current injection both to the active layer 15 in the resonator region 9 and to the active layer 15 in the amplification region 10.

In the present embodiment, the semiconductor laser (semiconductor laser section) 2 and the modulator (modulator section, having a length of 200 μm) 3 are connected to each other through a waveguide region (waveguide section, having a length of 50 μm) 20, as shown in FIG. 4. That is, a region (waveguide region) 20 where no contact layer and no electrode area formed is provided between the semiconductor laser 2 and the modulator 3 as a separation region for electrically separating the semiconductor laser 2 and the modulator 3 from each other. In the present embodiment, the layer structure of the waveguide region 20 provided as a separation region is the same as that of the modulator 3, as described below. However, the InGaAs contact layer 19 is removed to increase the separation resistance. An SiO₂ film 21 is formed on the p-type InP cladding layer 18.

In the present embodiment, as shown in FIG. 4, the layer structure of the modulator 3 and the layer structure of the waveguide region 20 are identical to each other, and an end surface of the amplification region (diffraction grating non-formation region) 10 of the semiconductor laser 2 and an end surface of the waveguide region 20 are connected to each other in a butt joint manner.

Further, in the present embodiment, as shown in FIG. 4, the layer structure of the semiconductor laser 2 and the layer structure of the modulator 3 and the waveguide region 20 differ from each other. That is, an active layer 16 in the modulator 3 and the waveguide region 20 has a layer structure different from that of the active layer 15 of the semiconductor laser 2 constructed as described above. The portions of these layer structures other than the active layers are identical to each other.

The modulator 3 and the waveguide region 20 are provided with the AlGaInAs-based strained-layer quantum well active layer 16 for the modulator in place of the above-described AlGaInAs-based strained-layer multiple quantum wall active layer 15, as shown in FIG. 4.

More specifically, the AlGaInAs-based strained-layer multiple quantum well active layer 16 for the modulator has, for example, as a multiple quantum well structure, a seven-layer structure formed of an AlGaInAs well layer having a compressive strain of 0.5% and a thickness of 9 nm and an AlGaInAs barrier layer having a tensile strain of 0.3%, a thickness of 5.1 nm and a bandgap wavelength of 1.34 μm, and is formed as an AlGaInAs/AlGaInAs compressively-strained multiple quantum well active layer having a photoluminescence wavelength of 1.49 μm. However, the present invention is not limited to this.

Also, a p-side electrode (upper electrode) 22 for the modulator formed of Ti/Pt/Au for example is provided on the p-type InGaAs contact layer 19, as shown in FIG. 4.

Further, an n-side electrode (lower electrode) 23 formed of AuGe/Au for example is provided on the back surface side of the substrate, as shown in FIG. 4.

In the present embodiment, after stacking each semiconductor layer and working the semiconductor layer into a mesa structure in stripe form, a high-resistance semiconductor layer (semi-insulating semiconductor layer: a Fe doped InP layer in the present embodiment) is embedded on opposite sides of the mesa structure to form a buried waveguide structure (a semi-insulating buried heterostructure (SI-BH structure)).

The inventors of the present invention have checked to which degree the optical output is improved when the length of the diffraction grating non-formation region 10 is increased with reference to the modulator integrated laser in which the diffraction grating 8 is formed through the entire length of the semiconductor laser 2. In the present embodiment, a plurality of modulator integrated lasers were made in which the length of the semiconductor laser 2 was set to 400 μm and the length of the diffraction grating non-formation region 10 was changed between 0 μm and 200 μm (the length of the diffraction grating formation region 9 was changed between 400 μm and 200 μm in this case). A plurality of modulator integrated lasers were also made in which the length of the semiconductor laser 2 was set to 500 μm and the length of the diffraction grating non-formation region 10 was changed between 0 μm and 200 μm (the length of the diffraction grating formation region 9 was changed between 500 μm and 300 μm in this case). If the length of the diffraction grating non-formation region 10 is 0 μm, the diffraction grating 8 is formed through the entire length of the semiconductor laser 2.

To provide the λ/4 phase shift 7 at a position deviating to the modulator 3 side from the center of the diffraction grating formation region 9, the position of the λ/4 phase shift 7 was set in such a linear relationship as to be at 170 μm, 230 μm and 290 μm from the device end surface (the rear end surface, the end surface on the left-hand side, as viewed in FIG. 4) when the length of the diffraction grating formation region 9 was set to 300 μm, 400 μm and 500 μm.

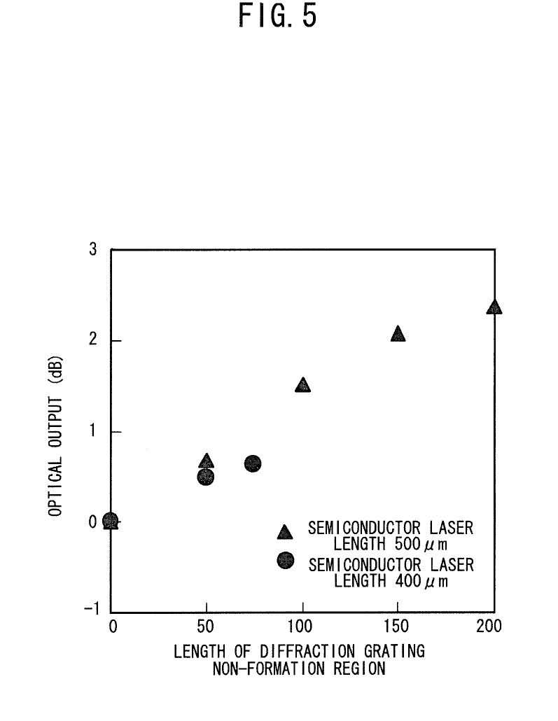

FIG. 5 is a graph formed by plotting the optical output power (dB) of modulated light normalized by the devices without diffraction grating nonformation region from each of the modulator integrated lasers 4 made as described above.

In FIG. 5, for ease of explanation, the optical output (dB) of modulated light from each of the modulator integrated lasers 4 made by setting the length of the semiconductor laser to 400 μm, setting the length of the diffraction grating non-formation region 10 to 0 μm, 50 μm and 75 μm and setting the length of the diffraction grating formation region 9 to 400 μm, 350 μm and 325 μm and the modulator integrated lasers 4 made by setting the length of the semiconductor laser to 500 μm, setting the length of the diffraction grating non-formation region 10 to 0 μm, 50 μm, 100 μm, 150 μm and 200 μm and setting the length of the diffraction grating formation region 9 to 500 μm, 450 μm, 400 μm, 350 μm and 300 μm is plotted.

It has been confirmed that, as shown in FIG. 5, the optical output power is increased irrespective of the length of the semiconductor laser 2 as the length of the diffraction grating non-formation region 10 is increased.

In the modulator integrated laser 4 in which the length of the semiconductor laser 2 was set to 500 μm and the length of the diffraction grating non-formation region 10 was set to 200 μm, however, an influence of residual reflection on the exit end surface of the device (the front side surface, the end surface on the modulator side, as viewed in FIG. 4) is conceivable. From this, it is thought that the gain is excessively high while gain saturation occurs in the amplification region, and it is probable that a length of 200 μm to which the length of the diffraction grating non-formation region 10 is set is slightly longer than the ideal length.

In increasing the optical output while avoiding an influence of return light due to residual reflection on the device end surface on the characteristics of the semiconductor laser 2 (while preventing the operation of the semiconductor laser 2 from becoming instable), therefore, it is preferable to set the length of the diffraction grating non-formation region 10 within the desirable range, below an excessively large length. More specifically, in a case where the length of the semiconductor laser 2 is set to 500 μm, it is preferable to set the length of the diffraction grating non-formation region 10 within the range from 50 to 150 μm (more preferably, to about 100 μm). The same setting may be made in a case where the length of the semiconductor laser 2 is set to 400 μm.

For functioning as the semiconductor laser 2, it is preferable to set the length of the resonator region (diffraction grating formation region) 9 to a length of 250 μm or more.

A method of manufacturing the optical semiconductor device (modulator integrated laser) according to the present embodiment will now be described.

The diffraction grating 8 including the λ/4 phase shift 7 is first formed in the region for formation of the resonator region (diffraction grating formation region) 9 of the semiconductor laser 2 (the region having the desired length from the device end surface) on the n-type InP substrate 1, for example, by using electron beam exposure and dry etching, as shown in FIG. 4. The diffraction grating 8 is not formed in the region for formation of the amplification region (diffraction grating non-formation region) 10 of the semiconductor laser 2 (the region formed on the modulator 3 side continuously with the resonator region 9 and having the desired length).

Subsequently, as shown in FIG. 4, the n-type InGaAsP waveguide layer 13 (having a thickness of 0.1 μm), the n-type InP layer 17 (having a thickness of 0.05 μm; an etching stop layer), the AlGaInAs/AlGaInAs compressive strained-layer multiple quantum well active layer 15 for the laser (a seven-layer structure which is formed of an AlGaInAs well layer having a compressive strain of 1.2% and a thickness of 5.1 nm and an AlGaInAs barrier layer having no strain, a thickness of 10 nm and a bandgap wavelength of 1.2 μm, and the active layer has a photoluminescence wavelength of 1.55 μm) and a portion of the p-type InP cladding layer 18 (having a thickness of about 0.15 μm for example) are successively grown on the n-type InP substrate 1 having the diffraction grating formation region 9 and the diffraction grating non-formation region 10, by using metal organic vapor phase epitaxy (MOVPE) for example. In this step, the same active layer 15 is formed in each of the regions for formation of the resonator region 9 and the amplification region 10 of the semiconductor laser 2.

Subsequently, an SiO₂ film is formed by using CVD for example, and the SiO₂ film on the region for formation of the modulator 3 (having a length of 200 μm for example) and the waveguide region 20 (having a length of 50 μm for example) provided as a separation region is thereafter removed by photolithography and etching for example.

The p-type InP cladding layer 18 and the AlGaInAs/AlGaInAs compressively-strained multiple quantum well active layer 15 are successively etched selectively by using wet etching for example, with the SiO₂ film used as a mask (SiO₂ mask).

Thereafter, the AlGaInAs/AlGaInAs compressively-strained quantum well active layer 16 for the modulator (e.g., a seven-layer structure which is formed of an AlGaInAs well layer having a compressive strain of 0.5% and a thickness of 9 nm and an AlGaInAs barrier layer having a tensile strain of 0.3%, a thickness of 5.1 nm and a bandgap wavelength of 1.34 μm, and the active layer has a photoluminescence wavelength of 1.49 μm) and a portion of the p-type InP cladding layer 18 (having a thickness of about 0.15 μm for example) are successively regrown for butt joint connection (butt joint growth) by using metal organic vapor phase epitaxy while leaving the SiO₂ film. The end surface of the diffraction grating non-formation region 10 of the semiconductor laser 2 and the end surface of the waveguide region 20 provided as a separation region are thereby connected to each other in a butt joint manner. Also, a layer structure different from the layer structure of the semiconductor laser 2 is formed in the region for formation of the modulator 3 and the waveguide region 20 provided as a separation region. Further, the same layer structure is formed in each of the region for formation of the modulator 3 and the region for formation of the waveguide region 20 provided as a separation region.

Subsequently, the SiO₂ film used as a mask is removed and the remaining portion of the p-type InP cladding layer 18 (having a thickness of about 1.5 μm for example) and the p-type InGaAs contact layer 19 (having a thickness of 0.3 μm) are thereafter grown successively on the entire surface of the wafer, thereby forming the p-type InP cladding layer 18 having a total thickness of about 1.65 μm.

Subsequently, SiO₂ film is formed on the entire surface and formed in stripe form by using photolithography for example, and a mesa structure having a width of 1.7 μm and a height of 3 μm for example is formed by using dry etching for example, with the SiO₂ film in stripe form as a mask (SiO₂ mask).

An Fe doped InP buried layer for example is grown (bury-regrown) on opposite sides (on two areas by the side of) of the mesa structure by using metal organic vapor phase epitaxy for example, thereby forming a semi-insulating buried heterostructure (SI-BH structure) as a current constriction structure.

The SiO₂ mask is thereafter removed and the p-type InGaAs contact layer 19 in the waveguide region 20 provided as a separation region is removed by using photolithography and etching for example. Subsequently, SiO₂ film (passivation film, insulating film) 21 is formed on the entire surface.

Only the SiO₂ film over the p-type InGaAs contact layer 19 on the regions for formation of the semiconductor laser 2 and the modulator 3 is removed and the p-side electrode (upper electrode) 14 for the laser and the p-side electrode (upper electrode) 22 for the modulator formed of Ti/Pt/Au for example are formed on the p-type InGaAs contact layer 19. One (single) p-side electrode 14 is formed in the region for formation of the resonator region 9 and the amplification region 10 of the semiconductor laser 2. On the other hand, the n-side electrode (lower electrode) 23 formed of AuGe/Au for example is formed on the back surface side of the substrate.

After cleavage for forming into an array form, the antireflection coatings 5 and 6 are formed on the opposite end surfaces, thereby completing the modulator integrated laser 4.

The structure, materials, composition and so on of the optical semiconductor device according to the above-described embodiment are only an example and the present invention is not limited to them.

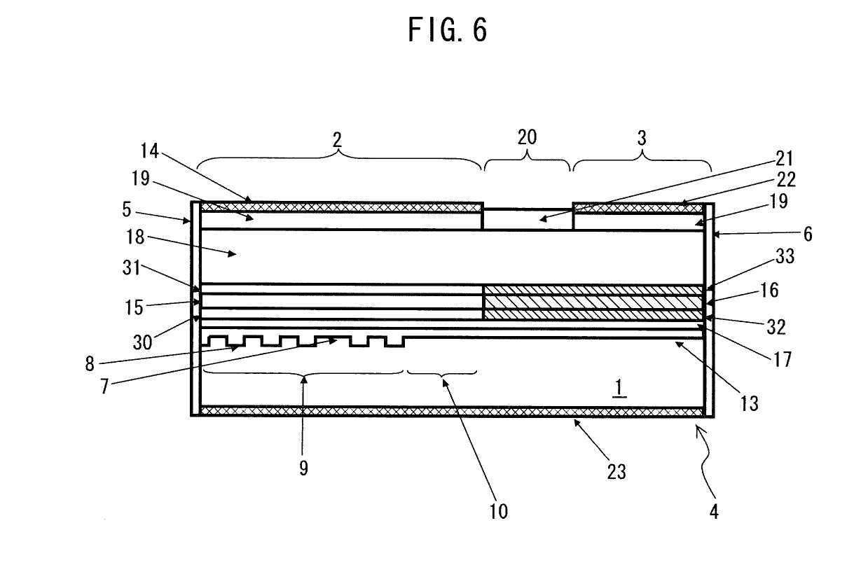

For example, while the structure having an active layer formed of AlGaInAs-based strained-layer multiple quantum well active layers 15 and 16 and having a stack of a well layer and a barrier layer has been described by way of example in the description of the embodiment, layers 30 to 33 for adjusting the light waveguide mode (light guide layers), called a separate confinement heterostructure (SCH), may be provided above and below the layers 15 and 16, as shown in FIG. 6. In regrowth for the modulator 3 in particular, the regrowth influence on the active layer 16 when growth from the SCH layer 32 is performed is smaller than that when growth from the active layer 16 is performed. In such a case, the growth can be facilitated if the SCH layer formed of an InGaAsP-based semiconductor material is used.

For example, in the semiconductor laser 2, a 50 nm-thick AlGaInAs layer (having a bandgap wavelength of 1.2 μm) may be provided as the n-side SCH layer 30 and a 50 nm-thick InGaAsP layer (having a bandgap wavelength of 1.05 μm) may be provided as the p-side SCH layer 31. The bandgap wavelength of the AlGaInAs barrier layer in the multiple quantum well active layer 15 for the laser is also 1.2 μm. On the other hand, in the modulator 3, a 50 nm-thick InGaAsP layer (having a bandgap wavelength of 1.05 μm) may be provided as the n-side SCH layer 32 and a 50 nm-thick InGaAsP layer having the bandgap wavelength continuously changing from 1.32 μm to 1.00 μm between the active layer and the cladding layer may be provided as the p-side SCH layer 33. The bandgap wavelength of the AlGaInAs barrier layer in the multiple quantum well active layer 16 for the modulator is 1.34 μm.

It has been confirmed that the modulator integrated laser 4 using such a layer structure and having the length of the semiconductor laser 2 set to 400 μm for example and having the length of the diffraction grating non-formation region 10 set to 75 μm for example has a high optical output of +6.5 dBm at the chip end at the time of modulation at 10 Gb/s (+3.5 dBm in the case of fiber coupling) at 50° C. under conditions enabling transmission over 80 km.

In the above-described embodiment, the layer structure of the modulator 3 and the layer structure of the waveguide region 20 are assumed to be identical to each other. However, the present invention is not limited to this. For example, the layer structure of the modulator and the layer structure of the waveguide region may be made different from each other.

In the above-described embodiment, an active layer formed of AlGaInAs-based strained-layer multiple quantum well active layers 15 and 16 is provided. However, the present invention is not limited to this. For example, a multiple quantum well layer based on a different material, e.g., an InGaAsP-based multiple quantum well active layer may alternatively be used.

In the above-described embodiment, a SI-BH structure is adopted as a waveguide structure. However, the present invention is not limited to this. For example, a different buried structure may be used and a ridge waveguide structure or the like may also be used.

A device using an integrated electric field absorption type of modulator has been described as a modulator by way of example in the above description of the embodiment. However, the present invention is not limited to this. For example, the present invention can also be applied to integrated devices having a Mach-Zehnder modulator, a directional-coupler-type modulator and the like integrated therein.

In the above-described embodiment, the diffraction grating 8 is formed on the semiconductor substrate 1. However, the present invention is not limited to this. Other various structures including diffraction gratings are conceivable. For example, diffraction gratings may be formed on a plurality of semiconductor layers stacked on a semiconductor substrate. More specifically, a diffraction grating may be formed by burying, in an n-type InP layer, recesses periodically formed in an n-type InGaAsP waveguide layer formed on an n-type InP substrate. A diffraction grating may be formed by periodically sectioning an n-type InGaAsP waveguide layer and burying the sectioned waveguide layers in an n-type InP layer. A diffraction grating may be formed not on the lower side of the active layer but on the upper side of the active layer. A diffraction grating may be formed so as to be exposed in a device surface. In a case where a ridge waveguide is used, a diffraction grating may be formed in side surfaces of the ridge waveguide.

In the above-described embodiment, a phase shift formed as λ/4 phase shift 7 is provided on the modulator 3 side of the center of the diffraction grating formation region 9. However, the present invention is not limited to this. For example, the phase shift may be provided at the center of the diffraction grating formation region. In this case, the optical output may decrease slightly but the mode stability is improved. The present invention can be applied to diffraction grating structures capable of single-mode oscillation, e.g., a structure having two λ/8 shifts even if the rear end surface (the device end surface on the semiconductor laser side) is an antireflection coating. In a case where a structure having two λ/8 shifts is used, the positions of the two λ/8 shifts may be set so that a mid point between the two λ/8 shifts is on the modulator side of the center of the diffraction grating formation region. For example, one λ/8 shift may be set at the center of the diffraction grating formation region and the other λ/8 shift may be set at a position shifted toward the modulator (as is the λ/4 phase shift shifted toward the modulator in the above-described embodiment).

An optical semiconductor device formed on an n-type InP substrate 1 has been described by way of example in the above description of the embodiment. However, the present invention is not limited to this. For example, an optical semiconductor device may be formed on a high-resistance InP substrate (SI-InP substrate). An optical semiconductor device may also be formed on a p-type InP substrate, although it is probable that the separation resistance between the semiconductor laser and the modulator will be reduced. An optical semiconductor device may also be formed a substrate formed of a material other than InP. For example, the present invention can be applied to an optical semiconductor device formed on a GaAs substrate for example. An active layer may be formed by using a GaInNAs-based material or quantum dots to realize even on a GaAs substrate an optical semiconductor device having a 1.3 μm wavelength band as a communication wavelength band.

In the above-described embodiment, an active layer of an AlGaInAs/AlGaInAs strained-layer multiple quantum well structure is provided. However, the present invention is not limited to this. For example, any other multiple quantum well structure, a thick-film bulk structure, a structure using quantum dots (e.g., InAs quantum dots or GaInAs quantum dots), etc., may be used.

The present invention is not limited to the above-described embodiment. Various changes and modifications may be made in the described embodiment without departing from the gist of the invention.

What is claimed is:

1. An optical semiconductor device comprising:
a semiconductor laser formed over a semiconductor substrate; and
a modulator formed over the semiconductor substrate and continuously arranged with the semiconductor laser,
wherein the semiconductor laser includes
a first region having a diffraction grating with a phase shift,
a second region arranged between the first region and the modulator, and in which the diffraction grating is not formed, and
a common active layer formed over the first region and the second region,
a first electrode injecting a current into the common active layer.

2. The optical semiconductor device according to claim 1, further comprising antireflection coatings formed on an end surface of the semiconductor laser and the modulator.

3. The optical semiconductor device according to claim 1, wherein the second region has a length within the range from 50 μm to 150 μm.

4. The optical semiconductor device according to claim 1, wherein the first region has a length equal to or larger than 250 μm.

5. The optical semiconductor device according to claim 1, wherein the phase shift is a λ/4 phase shift.

6. The optical semiconductor device according to claim 1, wherein the phase shift is formed on the modulator side of a center of the first region.

7. The optical semiconductor device according to claim 1, wherein the modulator is one of an electric field-absorption-type modulator, a Mach-Zehnder modulator and a directional-coupler-type modulator.

8. The optical semiconductor device according to claim 1, wherein the modulator includes a second active layer formed over the semiconductor substrate and having a layer structure different from the common active layer.

9. The optical semiconductor device according to claim 8, further comprising a waveguide region formed over the substrate and arranged between the semiconductor laser and the modulator.

10. The optical semiconductor device according to claim 9, wherein the second active layer is formed to the waveguide region.

11. The optical semiconductor device according to claim 10, wherein the modulator has a second electrode through which a voltage is applied to the second active layer of the modulator.

12. The optical semiconductor device according to claim 11, further comprising an insulating film which separates the first electrode and the second electrode, and which is formed over the waveguide region.

13. The optical semiconductor device according to claim 9, wherein an end surface of the second region and an end surface of the waveguide region are connected in a butt joint manner.

14. The optical semiconductor device according to claim 8, wherein the common active layer and the second active layer includes a quantum well active layer containing AlGaInAs.

15. The optical semiconductor device according to claim 14, wherein the quantum well active layer is of a multilayer structure.

16. The optical semiconductor device according to claim 8, wherein the second active layer of the modulator includes a quantum well active layer containing AlGaInAs.

17. The optical semiconductor device according to claim 16, wherein the quantum well active layer is of a multilayer structure.

18. The optical semiconductor device according to claim 8, further comprising an SCH layer in which the common active layer and the second active layer are interposed.

19. The optical semiconductor device according to claim 8, further comprising a cladding layer formed over the common active layer and the second active layer.

20. The optical semiconductor device according to claim 1, wherein the semiconductor substrate is an InP substrate.
